(19) United States
(12) Patent Application Publication
(10) Pub. No.: US 2026/0179712 A1
(43) Pub. Date: Jun. 25, 2026

(54) MEMORY CONTROLLERS, MEMORY SYSTEMS, SYSTEMS AND OPERATING METHODS, STORAGE MEDIUMS

(71) Applicant: Yangtze Memory Technologies Co., Ltd., Wuhan (CN)

(72) Inventors: Biao Yang, Wuhan (CN); Fei Chen, Wuhan (CN); Suyi Liu, Wuhan (CN)

(21) Appl. No.: 19/215,960

(22) Filed: May 22, 2025

(30) Foreign Application Priority Data
Dec. 19, 2024 (CN) 202411885446.7

(51) Int. Cl. G11C 29/52; G11C 16/08; G11C 16/26

(52) U.S. Cl. CPC G11C 29/52; G11C 16/08; G11C 16/26

(57) ABSTRACT

An implementation of the present disclosure provides a memory controller, a memory system, a system and its operating method, and a storage medium; wherein the memory controller is configured to obtain a first result based on a first set of read data and a second set of read data; obtain a second result based on a third set of read data and a fourth set of read data; perform a logical operation on the first result and the second result to obtain first flip information; perform a decoding operation based on the first flip information.

### CROSS-REFERENCE TO RELATED APPLICATION

This application claims priority to and the benefit of Chinese Patent Application 202411885446.7, filed on Dec. 19, 2024, which is hereby incorporated by reference in its entirety.

### TECHNICAL FIELD

Implementations of the present disclosure relate to the field of semiconductor technology, and particularly to memory controllers, memory systems, systems and its operating methods, and storage mediums.

### BACKGROUND

A memory system is a storage device used to store information in modern information technology. As a typical non-volatile semiconductor memory, NAND (Not And) type memory has gradually become the mainstream product in the storage market due to its high storage density, controllable production cost, suitable program and erase speed, and retention characteristics.

### BRIEF DESCRIPTION OF THE DRAWINGS

FIG. 1 is a schematic diagram of an example system with a memory system according to an implementation of the present disclosure.

FIG. 2A is a schematic diagram of an example memory card with a memory system according to an implementation of the present disclosure.

FIG. 2B is a schematic diagram of an example solid-state driver with a memory system according to an implementation of the present disclosure.

FIG. 3A is a schematic diagram of the distribution of memory cells of a three-dimensional NAND type memory according to an implementation of the present disclosure.

FIG. 3B is a schematic diagram of an example memory including a peripheral circuit according to an implementation of the present disclosure.

FIG. 4 is a schematic cross-sectional view of an array of memory cells including NAND type memory strings according to an implementation of the present disclosure.

FIG. 5 is a schematic diagram of an example memory device including an array of memory cells and a peripheral circuit according to an implementation of the present disclosure.

FIG. 6 is a schematic diagram of the composition structure of a memory system provided by an implementation of the present disclosure.

FIG. 7 shows a write data and level indicator check code provided by an implementation of the present disclosure.

FIG. 8 is a schematic diagram of the way of a read with level indicator provided by an implementation of the present disclosure.

FIG. 9 is a schematic diagram of the distribution relationship between read voltage and threshold voltage provided by an implementation of the present disclosure.

FIG. 10 is a schematic diagram of multiple read voltage intervals provided by an implementation of the present disclosure.

FIG. 11 is a first schematic diagram of an example system with a memory device provided by an implementation of the present disclosure.

FIG. 12 is a second schematic diagram of an example system with a memory device provided by an implementation of the present disclosure.

FIG. 13 is a third schematic diagram of an example system with a memory device provided by an implementation of the present disclosure.

FIG. 14 is a schematic flowchart of a method of operating a memory system provided by an implementation of the present disclosure.

In the above figures (which may not necessarily be drawn to scale), similar reference numbers may describe similar components in different views. Similar reference numbers with different letter suffixes may represent different examples of similar components. The accompanying figures generally illustrate, by way of example and not limitation, various implementations discussed herein.

### DETAILED DESCRIPTION

Example implementations disclosed in the present disclosure will be described in more detail below with reference to the accompanying drawings. Although example implementations of the present disclosure are shown in the accompanying drawings, it should be understood that the present disclosure may be implemented in various forms and should not be limited by the implementations described herein. On the contrary, providing these implementations are to enable a more thorough understanding of the present disclosure and to fully convey the scope of the present disclosure to those skilled in the art.

In the following description, a large number of specific details are presented to provide a more thorough understanding of the present disclosure. However, it will be apparent to those skilled in the art that the present disclosure may be implemented without one or more of these details. In other examples, in order to avoid confusion with the present disclosure, some well-known technical features in this field have not been described. That is, not all features of the actual implementation will be described here, and well-known functions and structures will not be described in detail.

In the accompanying drawings, for clarity, dimensions of layers, regions, and elements, as well as their relative sizes, may be exaggerated. The same reference numbers always indicate the same components.

It should be understood that when an element or layer is referred to as “on”, “adjacent to”, “connected to”, or “coupled to” other elements or layers, it may be directly on, adjacent to, connected to, or coupled to other elements or layers, or there may be an intervening element or layer. On the contrary, when an element is referred to as “directly on”, “directly adjacent to”, “directly connected to”, or “directly coupled to” other elements or layers, there are no intervening elements or layers. It should be understood that although terms such as first, second, third, etc. may be used to describe various elements, components, regions, layers, and/or portions, these elements, components, regions, layers, and/or portions should not be limited by these terms. These terms are only used to distinguish one element, component, region, layer or portion from another element, component, region, layer or portion. Therefore, without departing from the teachings of this disclosure, a first element, component, region, layer, or portion discussed below may be indicated as a second element, component, region, layer, or portion. When discussing a second element, component, region, layer, or portion, it does not necessarily mean that the present disclosure necessarily includes a first element, component, region, layer, or portion.

Spatial relationship terms such as “below”, “beneath”, “lower”, “under”, “on”, “above”, etc. may be used here for ease of description to describe the relationship between an element or feature and other elements or features shown in the figures. It should be understood that in addition to orientations shown in the figures, spatial relationship terms are intended to also include different orientations of devices in use and operation. For example, if a device in the figures is flipped, then an element or feature described as “below” or “under” or “beneath” other elements or features will be oriented “above” the other elements or features. Therefore, example terms “below” and “under” may include both upper and lower orientations. The device may be oriented additionally (rotated 90 degrees or other orientations) and spatial descriptors used herein are explained accordingly.

Terms used herein is only for the purpose of describing implementations and is not intended as a limitation of the present disclosure. When used herein, “a”, “an” and “the/said” in singular forms are also intended to include the plural form, unless the context clearly indicates otherwise. It should also be understood that the terms “comprise” and/or “include”, when used in this specification, determine the presence of the described features, integers, steps, operations, elements, and/or components, but do not exclude the presence or addition of one or more other features, integers, steps, operations, elements, components, and/or groups. When used herein, the term “and/or” includes any and all combinations of the listed items.

In order to have a more detailed understanding of characteristics and technical content of implementations of the present disclosure, implementations of implementations of the present disclosure will be described in detail below in conjunction with the accompanying drawings. The accompanying drawings are for reference only and are not intended to limit implementations of the present disclosure.

A memory device in implementations of the present disclosure includes but is not limited to a three-dimensional NAND type memory. For ease of understanding, take the three-dimensional NAND type memory as an example for illustration.

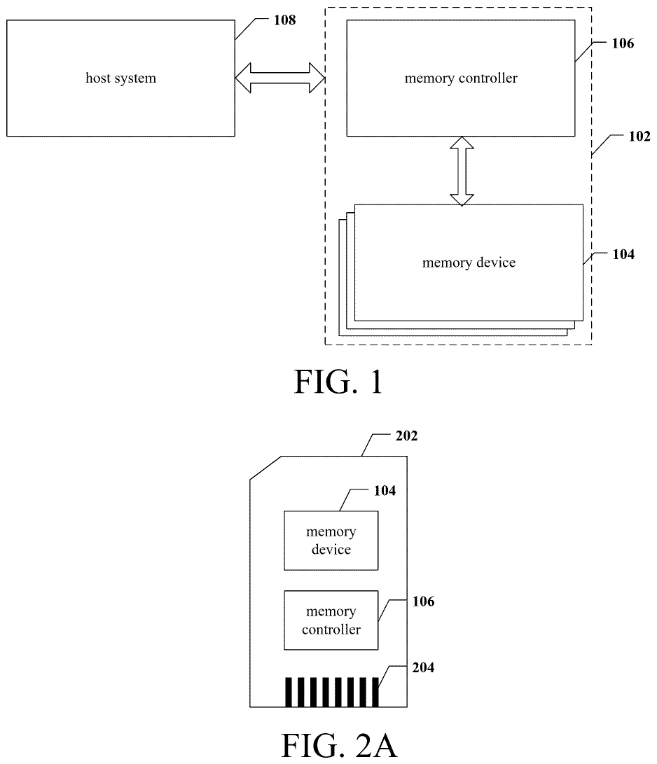

FIG. 1 shows a block diagram of an example system 100 with memory devices in accordance with some aspects of the present disclosure. System 100 may be a mobile phone, desktop computer, laptop computer, tablet computer, vehicle computer, game console, printer, positioning device, wearable electronic device, smart sensor, virtual reality (VR) device, augmented reality (AR) device, or any other suitable electronic device with storage. As shown in FIG. 1, system 100 may include a host system 108 and a memory system 102 having one or more memory devices 104 and a memory controller 106. The host system 108 may be a processor of an electronic device (e.g., a central processing unit (CPU)) or a system on chip (SoC) (e.g., an application processor (AP)). The host system 108 may be configured to send or receive data to or from a memory device 104.

According to some implementations, the memory controller 106 is coupled to the memory device 104 and the host system 108, and configured to control the memory device 104. The memory controller 106 may manage data stored in the memory device 104 and communicate with the host system 108. In some implementations, the memory controller 106 is designed to operate in low duty cycle environments, such as Secure Digital (SD) cards, Compact Flash (CF) cards, Universal Serial Bus (USB) flash drivers, or other media used in electronic devices such as personal calculators, digital cameras, mobile phones, etc. In some implementations, the memory controller 106 is designed to operate in high duty cycle environments such as Solid State Disk (SSD) or Embedded Multimedia Card (eMMC). SSD or eMMC are used as data storage for mobile devices such as smartphones, tablets, laptop computers, and enterprise storage arrays.

The memory controller 106 may be configured to control operations of the memory device 104, such as read, erase, and program operations. The memory controller 106 may also be configured to manage various functions related to data stored or to be stored in the memory device 104, including but not limited to bad block management, garbage collection, logical to physical address translation, loss balancing, etc. In some implementations, the memory controller 106 is further configured to process error correction codes (ECC) for data read from or written to the memory device 104. The memory controller 106 may also perform any other suitable function, such as formatting the memory device 104. The memory controller 106 may communicate with external devices (such as the host system 108) according to a specific communication protocol. For example, the memory controller 106 may communicate with external devices through at least one of various interface protocols, such as USB protocol, MMC protocol, Peripheral Component Interconnect (PCI) protocol, PCI Express (PCI-E) protocol, Advanced Technology Attachment (ATA) protocol, Serial ATA protocol, Parallel ATA protocol, Small Computer Small Interface (SCSI) protocol, Enhanced Small Disk Interface (ESDI) protocol, Integrated Driver Electronics (IDE) protocol, Firewire protocol, etc.

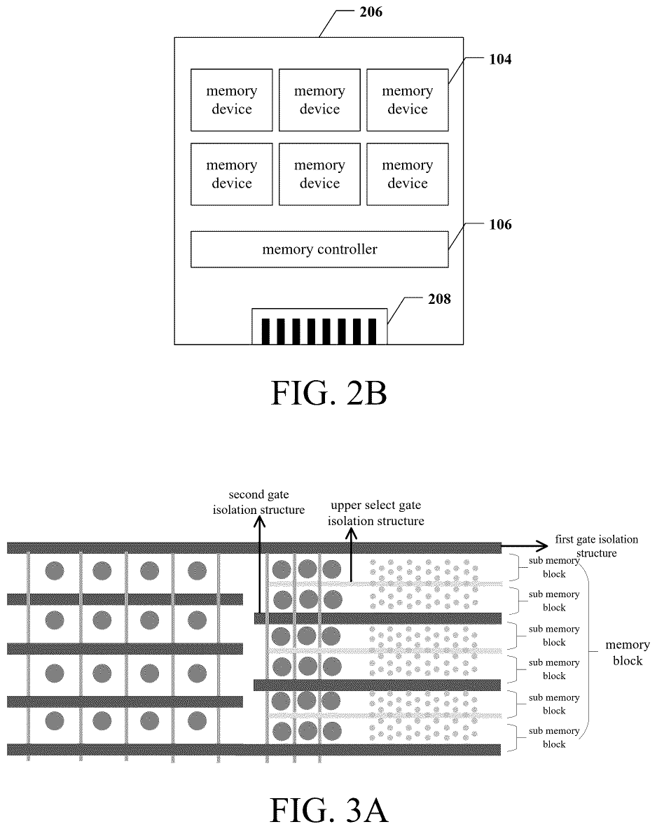

The memory controller 106 and one or more memory devices 104 may be integrated into various types of memory devices, such as included in the same package (e.g., Universal Flash Storage (UFS) package or eMMC package). That is to say, the memory system 102 may be implemented and packaged into different types of terminal electronic products. In one example shown in FIG. 2A, the memory controller 106 and a single memory device 104 may be integrated into the memory card 202. Memory card 202 may include PC card (PCMCIA, Personal Computer Memory Card International Association), CF card, Smart Media (SM) card, memory stick, multimedia card (MMC, Reduced-Size MMC (RS-MMC), MMCmicro), SD card (SD, miniSD, microSD, Secure Digital High Capacity (SDHC)), UFS, etc. The memory card 202 may also include a memory card connector 204 that couples the memory card 202 to a host (e.g., host system 108 in FIG. 1). In another example as shown in FIG. 2B, the memory controller 106 and multiple memory devices 104 may be integrated into SSD 206. The SSD 206 may also include an SSD connector 208 that couples the SSD 206 to a host (e.g., host system 108 in FIG. 1). In some implementations, the storage capacity and/or operating speed of SSD 206 is greater than the storage capacity and/or operating speed of memory card 202.

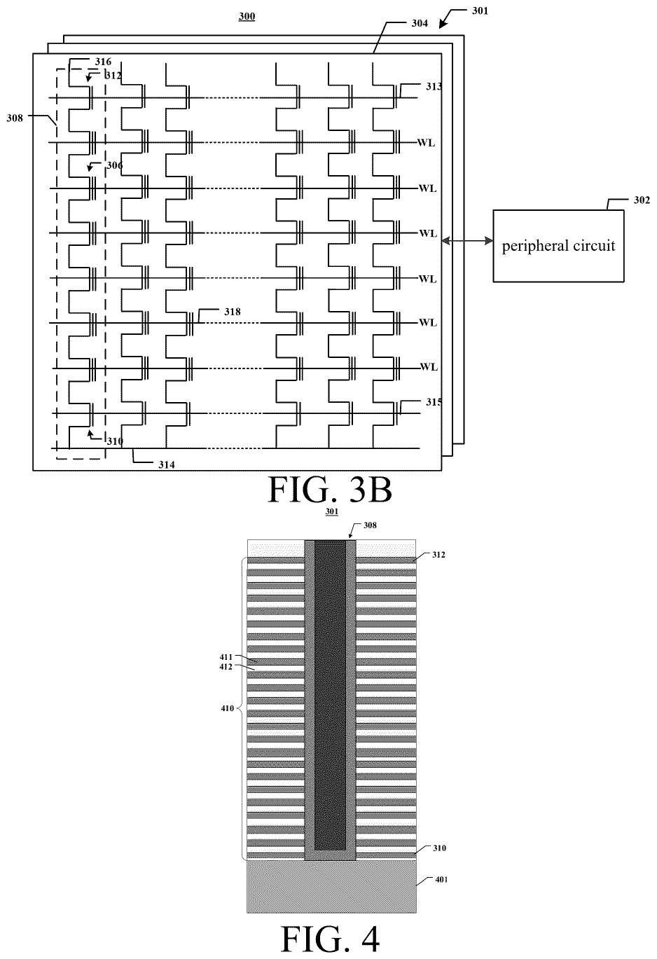

FIG. 3A shows a schematic diagram of the structure of an array of memory cells in a three-dimensional NAND type memory. As shown in FIG. 3A, the array of memory cells of the three-dimensional NAND type memory is composed of several rows of staggered in-parallel memory cell rows parallel to a gate isolation structure. Every two rows of memory cell rows are separated by the gate isolation structure and the upper select gate isolation structure, and each memory cell row includes multiple memory cells. The gate isolation structure may include a first gate isolation structure and a second gate isolation structure. The first gate isolation structure divides the array of memory cells into multiple memory blocks, and the multiple second gate isolation structures may divide the memory blocks into multiple sub memory blocks. A memory block shown in FIG. 3A contains 6 sub memory blocks. In practical applications, the number of sub memory blocks in a memory block is not limited to this.

In some implementations, each memory block may be coupled with multiple word lines (WLs), and multiple memory cells coupled to each word line controlled individually form a page. For example, in FIG. 3A, all memory cells in each sub memory block are coupled to form a page.

It should be noted that the number of rows of memory cell rows between the gate isolation structure and the upper select gate isolation structure shown in FIG. 3A is only an example demonstration and is not used to limit the number of memory cell rows contained in a storage area of a three-dimensional NAND type memory disclosed in this disclosure. In practical applications, the number of memory cell rows contained in a storage area may be adjusted according to actual situations, such as 2, 4, 8, 16, etc.

FIG. 3B shows a schematic circuit diagram of an example memory device 300 including a peripheral circuit in accordance with some aspects of the present disclosure. The memory device 300 may be an example of the memory device 104 in FIG. 1. The memory device 300 may include an array of memory cells 301 and a peripheral circuit 302 coupled to the array of memory cells 301. Take the array of memory cells 301 as an example of an array of three-dimensional NAND type memory cells, where a memory cell 306 is a NAND type memory cell, the memory cell 306 is provided in the form of an array of memory strings 308, and each memory string 308 extends vertically above a substrate (not shown). In some implementations, each memory string 308 includes multiple memory cells 306 coupled in series and stacked vertically. Each memory cell 306 may maintain continuous analog values, such as voltage or charge, depending on the number of electrons captured within the region of the memory cell 306. Each memory cell 306 may be a floating gate type memory cell including a floating gate transistor, or a charge capture type memory cell including a charge capture transistor.

In some implementations, each memory cell 306 is a single-level cell (SLC) that has two possible memory states and thus may store one bit of data. For example, a first memory state ‘0’ may correspond to a first voltage range, and a second memory state ‘1’ may correspond to a second voltage range. In some implementations, each memory cell 306 is a multi-level cell (MLC) capable of storing more than one bit of data in more than four memory states. For example, a MLC may store two bits of data per cell (also known as a double level cell), three bits of data per cell (also known as a trinary level cell (TLC)), four bits of data per cell (also known as a quad-level cell (QLC)), five bits of data per cell (also known as a penta-level cell (PLC)), or more than five bits of data per cell. Each MLC may be programmed to take a range of possible nominal storage values. In one example, if each MLC stores two bits of data, the MLC may be programmed to take one of three possible programming levels from an erase state by writing one of three possible nominal storage values to the cell, and a fourth nominal storage value may be used for the erase state.

As shown in FIG. 3B, each memory string 308 may include a lower select transistor (also known as a source side select transistor, which includes a source select gate BSG 310 (e.g., a bottom select gate (BSG)) at its source terminal and an upper select transistor (also known as a drain side select transistor, which includes a drain select gate TSG 312 (e.g., a top select gate (TSG)) at its drain terminal. The source select gate BSG 310 and the drain select gate TSG 312 may be configured to activate a selected memory string 308 during read and program operations. In some implementations, the sources of memory strings 308 in the same memory block 304 are coupled through the same source line (SL) 314 (e.g., a common SL). In other words, according to some implementations, all memory strings 308 in the same memory block 304 have an array common source (ACS). According to some implementations, the TSG 312 of each memory string 308 is coupled to a corresponding bit line (BL) 316, from which data may be read or written via an output bus (not shown). In some implementations, each memory string 308 is configured to be selected or deselected by applying a selection voltage (e.g., higher than the threshold voltage of a transistor with TSG 312) or a deselection voltage (e.g., 0V) to the corresponding TSG 312 via one or more TSG lines 313 and/or by applying a selection voltage (e.g., higher than the threshold voltage of a transistor with BSG 310) or a deselection voltage (e.g., 0V) to the corresponding BSG 310 via one or more BSG lines 315.

As shown in FIG. 3B, the memory string 308 may be organized into multiple memory blocks 304, each of which may have a common source line 314 (e.g., coupled to ground). In some implementations, each memory block 304 is a basic data unit used for erase operations, that is, all memory cells 306 on the same memory block 304 are erased simultaneously. To erase the memory cells 306 in the selected memory block 304, the source line 314 coupled to the selected memory block 304 and the unselected memory blocks 304 in the same side as the selected memory block 304 may be biased with an erase voltage (Vers), e.g., a high positive voltage (e.g., 20V or higher). It should be understood that in some examples, an erase operation may be performed at the level of a half memory block, at the level of a quarter memory block, or at the level of any suitable number of memory blocks or any suitable fraction of memory blocks. The memory cells 306 of adjacent memory strings 308 may be coupled through word lines 318, and the word lines 318 select which row of memory cells 306 is affected by read and program operations. In some implementations, in combination with the previous FIG. 3A, multiple memory cells are isolated by upper select gate isolation structures and gate isolation structures, and multiple memory cells between the upper select gate isolation structures and the gate isolation structures are arranged in multiple memory cell rows, with each memory cell row parallel to the gate isolation structures and the upper select gate isolation structures.

Referring to FIGS. 3A and 3B, each memory cell 306 in multiple memory cells is coupled to a corresponding word line 318, and each memory string 308 is coupled to a corresponding bit line 316 through a corresponding select transistor (as an upper select transistor).

FIG. 4 shows a cross-sectional schematic diagram of an example array of memory cells 301, including memory strings 308 taking NAND as an example, in accordance with some aspects of the present disclosure. As shown in FIG. 4, the array of NAND memory cells 301 may include a stacked structure 410, which includes multiple gate layers 411 and multiple insulation layers 412 alternately stacked in sequence, and a channel structure vertically penetrating the gate layers 411 and insulation layers 412, wherein the channel structure is coupled to each gate layer to form a memory cell, and the channel structure is coupled to multiple gate layers in the stacked structure 410 to form a memory string 308. The gate layer 411 and the insulating layer 412 may be alternately stacked, with adjacent gate layers 411 separated by an insulating layer 412.

The composition materials of the gate layer 411 may include conductive materials. Conductive materials include but are not limited to tungsten (W), cobalt (Co), copper (Cu), aluminum (Al), polycrystalline silicon, doped silicon, silicides, or any combination thereof. In some implementations, each gate layer 411 includes a metal layer, such as a tungsten layer. In some implementations, each gate layer 411 includes a doped polycrystalline silicon layer. Each gate layer 411 may include a control gate surrounding memory cells. The gate layer 411 at the top of the stacked structure 410 may extend laterally as an upper select gate line, the gate layer 411 at the bottom of the stacked structure 410 may extend laterally as a lower select gate line, and the gate layer 411 extending laterally between the upper and lower select gate lines may serve as a word line layer.

In some implementations, the stacked structure 410 may be disposed on the substrate 401. The substrate 401 may include silicon (e.g., monocrystalline silicon), silicon germanium (SiGe), gallium arsenide (GaAs), germanium (Ge), silicon on insulator (SOI), germanium on insulator (GOI), or any other suitable material.

In some implementations, the memory string 308 includes a channel structure extending vertically through the stacked structure 410. In some implementations, the channel structure includes channel vias filled with (one or more) semiconductor material (e.g., as a semiconductor channel) and (one or more) dielectric material (e.g., as a memory film). In some implementations, the semiconductor channel includes silicon, such as polycrystalline silicon. In some implementations, the memory film is a composite dielectric layer comprising a tunneling layer, a storage layer (also known as a “charge capture/storage layer”), and a barrier layer. The channel structure may have a cylindrical shape (e.g., pillar shape). According to some implementations, the semiconductor channel, tunneling layer, storage layer, and barrier layer are arranged radially from the center of the pillar towards the outer surface of the pillar in order. The tunneling layer may include silicon oxide, silicon oxynitride, or any combination thereof. The storage layer may include silicon nitride, silicon oxynitride, or any combination thereof. The barrier layer may include silicon oxide, silicon oxynitride, high dielectric constant (high k) dielectric, or any combination thereof. In one example, the memory film may include a composite layer of silicon oxide/silicon oxynitride/silicon oxide (ONO).

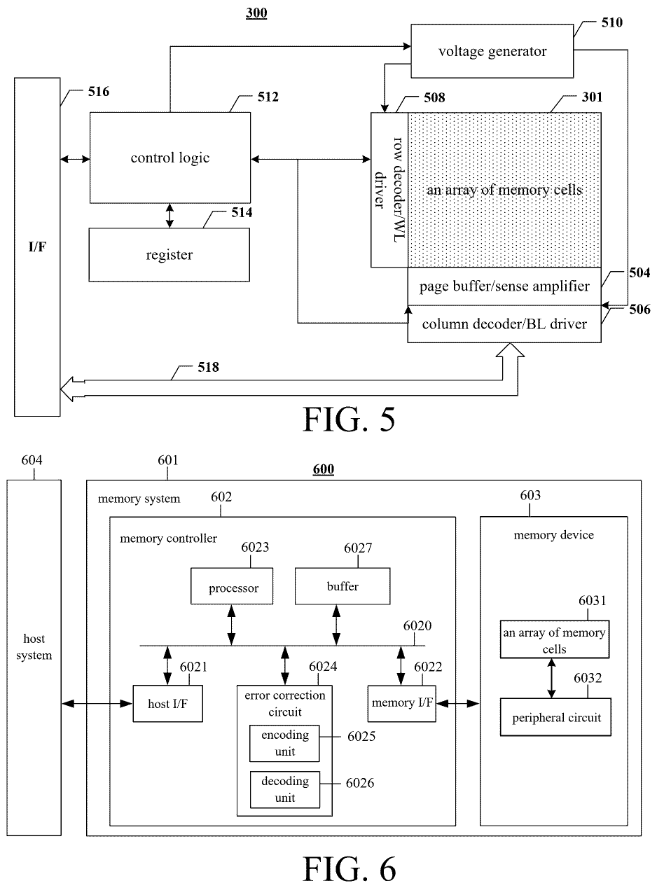

Referring back to FIG. 3B, the peripheral circuit 302 may be coupled to the array of memory cells 301 through bit lines 316, word lines 318, source lines 314, BSG lines 315, and TSG lines 313. The peripheral circuit 302 may include any suitable analog, digital, and mixed signal circuit for facilitating operations of the array of memory cells 301 by applying voltage and/or current signals to and sensing voltage and/or current signals from each target memory cell 306 via bit lines 316, word lines 318, source lines 314, BSG lines 315, and TSG lines 313. The peripheral circuit 302 may include various types of peripheral circuits formed with metal oxide semiconductor (MOS) technology. For example, FIG. 5 illustrates some example peripheral circuits. The peripheral circuit 302 includes page buffer/sense amplifier 504, column decoder/bit line driver 506, row decoder/word line driver 508, voltage generator 510, control logic 512, register 514, interface 516, and data bus 518. It should be understood that in some examples, additional peripheral circuits not shown in FIG. 5 may also be included.

The page buffer/sense amplifier 504 may be configured to read data from the array of memory cells 301 and program (write) data to the array of memory cells 301 according to control signals from the control logic 512. In one example, the page buffer/sense amplifier 504 may store programming data (write data) to be programmed into the array of memory cells 301. In another example, the page buffer/sense amplifier 504 may perform a program verification operation to ensure that data has been correctly programmed into the memory cell 306 coupled to the selected word line 318. In yet another example, the page buffer/sense amplifier 504 may also sense low-power signals representing bits of data stored in the memory cell 306 from the bit line 316, and amplify small voltage swings to recognizable logic levels during read operations. The column decoder/bit line driver 506 may be configured to be controlled by the control logic 512 and select one or more memory strings 308 by applying bit line voltages generated from the voltage generator 510.

The row decoder/word line driver 508 may be configured to be controlled by the control logic 512, and to select/deselect the memory block 304 of the array of memory cells 301 and select/deselect the word line 318 of the memory block 304. The row decoder/word line driver 508 may also be configured to use a word line voltage generated from the voltage generator 510 to drive the word line 318. In some implementations, the row decoder/word line driver 508 may also select/deselect and drive the BSG line 315 and TSG line 313. As described in detail below, the row decoder/word line driver 508 is configured to perform programming operations on the memory cell 306 coupled to the selected word line(s) 318. The voltage generator 510 may be configured to be controlled by the control logic 512 and generate a word line voltage (e.g., read voltage, program voltage, pass voltage, channel boost voltage, verification voltage, etc.), bit line voltage, and source line voltage to be supplied to the array of memory cells 301.

The control logic 512 may be coupled to every other part of the peripheral circuit described above, and configured to control operations of every other part of the peripheral circuit. Register 514 may be coupled to control logic 512 and includes a status register, command register, and address register for storing status information, command opcodes (OP codes), and command addresses used to control operations of each peripheral circuit. Interface 516 may be coupled to control logic 512 and serve as a control buffer to buffer control commands received from a host system (not shown) and relay them to control logic 512, and to buffer status information received from control logic 512 and relay them to the host system. Interface 516 may also be coupled to column decoder/bit line driver 506 via data bus 518 and serve as a data input/output (I/O) interface and data buffer to buffer data and relay the data to the array of memory cells 301, or relay or buffer data from the array of memory cells 301.

For a NAND type memory, as storage capacity of the memory increases, the number of memory cell layers increases, and the number of codes also increases, the reliability of data decreases accordingly, in some examples coarse data in Multi-Pass Programming operations in the case of high code numbers. It should be noted that coarse data refers to the written data in a coarse programming operation, which is the first programming operation in the multi-pass programming operation. Considering the poor reliability of these coarse data, it is necessary to flush them from a multi-level cell such as QLC into a single-level cell SLC. This creates a significant gap in the demand for capacitor power due to abnormal power outages, which has become one of the important issues limiting the development of QLC enterprise level solid-state drive. In this case, the way of a read with level indicator provides a great way to greatly extend the readable life of coarse data through simple logical operations. However, there are still issues with the soft decoding operation that adapts to the read with level indicator, which prevents further extension of the readable-back life of the coarse data.

Based on one or more of the above issues, an implementation of the present disclosure provides a memory controller, memory system, system and its operating method, and storage medium that may support/adapt the soft decoding operation for the way of a read with level indicator, improve the error correction performance and read performance of the memory system, and thereby enhance the readable-back life of data.

Referring to FIG. 6, FIG. 6 shows a block diagram of a system 600. System 600 includes a host system 604 and a memory system 601. The host system 604 and the memory system 601 are connected in any suitable manner, and the host system 604 may be an electronic device such as a personal computer, mobile terminal, etc. The memory system 601 includes a memory controller 602 and a memory device 603. The memory controller 602 and memory device 603 may be coupled in any suitable manner.

The memory controller 602 may include a host interface (I/F) 6021, a memory I/F 6022, a processor 6023, an error correction (ECC) circuit 6024, a buffer 6027, and an internal bus 6020. The memory device 603 may be a non-volatile semiconductor memory for storing data, such as NAND type memory, wherein the host I/F 6021 outputs commands, data, etc. received from the host system 604 to the internal bus 6020, and sends data read from the memory device 603, responses from the processor 6023, etc. to the host system 604.

The memory I/F 6022 controls the process of writing data and the like to memory device 603 and the process of reading data and the like from memory device 603, based on instructions from processor 6023. Processor 6023 controls the memory system 601 as a whole. Processor 6023 is for example a central processing unit (CPU), microprocessor (MPU), etc. When receiving a command from host system 604 via host I/F 6021, processor 6023 performs control based on the command. For example, processor 6023 instructs memory I/F 6022 to write data and check code to memory device 603 based on commands from host system 604. In addition, processor 6023 instructs memory I/F 6022 to read data and check code from memory device 603 based on commands from host system 604.

The error correction circuit 6024 includes an encoding unit 6025 and a decoding unit 6026. The encoding unit 6025 encodes the write data of a predetermined size written into the same page to generate a check code. The verification data is written to the page of data that has been written to become the basis for encoding, and the check code is used for decoding by the decoding unit 6026. Buffer 6027 temporarily stores data received from host system 604 before storing it in memory device 603, and temporarily stores data read from memory device 603 before sending it to host system 604.

The memory device 603 may include an array of memory cells 6031 and a peripheral circuit 6032. The array of memory cells 6031 and peripheral circuit 6032 may be coupled in any suitable manner. The array of memory cells 6031 may include multiple memory cells, and the peripheral circuit 6032 may include a sense amplifier circuit, row decoder, column decoder, etc. The peripheral circuit 6032 is used to receive commands, access each memory cell in the array of memory cells 6031 independently based on parsing the commands, and perform read, write, or refresh operations, etc. on the data stored in the accessed memory cells.

In some implementations, the host system 604 may send a first instruction and write data to the memory controller 602. The first instruction is to instruct to perform a write operation on the write data, such as storing the write data in an array of memory cells. The memory controller sends a second instruction and write data to the memory device in response to the first instruction. The second instruction is to instruct to store the write data in the array of memory cells.

When performing a write operation, a set of level indicator check codes is generated based on the write data, wherein the level indicator check code may be generated by the memory controller and cached in the memory controller for backup, and then stored in the array of memory cells; or generated by calculation when the memory device storing the write data in the array of memory cells, and stored in the array of memory cells. In some implementations, the write data and level indicator check code are stored in different memory cells of the array of memory cells, for example, the write data is stored in a first memory cell, and the level indicator check code is stored in a second memory cell.

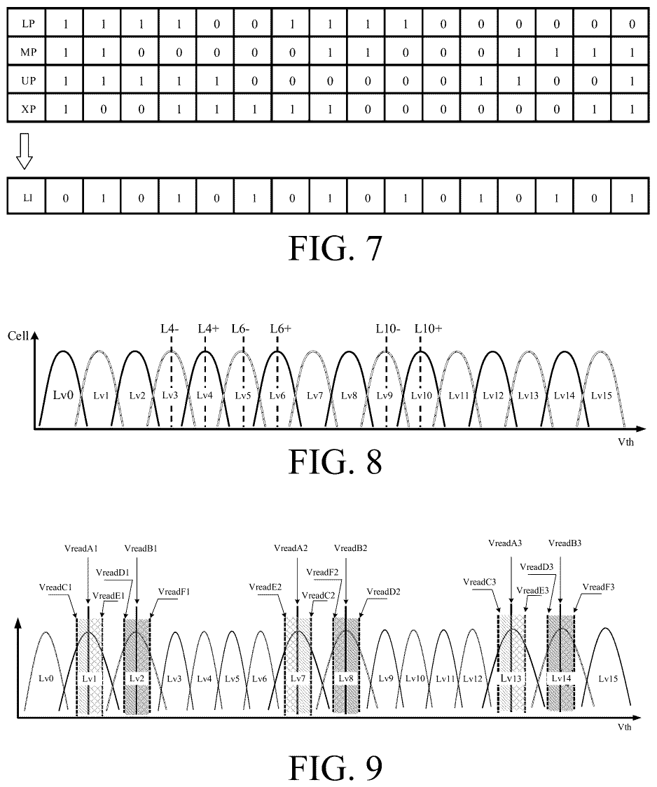

Referring to FIG. 7, FIG. 7 shows a schematic diagram of a set of write data and corresponding level indicator check codes, wherein the level indicator check code L1 is obtained by performing a XOR operation on the write data (LP, MP, UP, and XP data).

It should be noted that when the memory cell is configured to store M bits of data, the M bits of data belong to different classes of pages, respectively. The maximum number of memory states for multiple memory cells coupled to a word line is 2^{M}, and 2^{M} memory states need to be distinguished by 2^{M}−1 levels of read voltages, wherein each class of page corresponds to at least one level of read voltage, and M is an integer greater than 1.

For example, referring to FIG. 7, when M=4, the memory cell may store 4 bits of data (e.g., QLC), and the 4 bits of data stored in QLC may belong to a lower page (LP), a middle page (MP), an upper page (UP), and an extra page (XP), respectively. In QLC, data may be read on a class page-by-class page basis in units of a class of page. For example, the lower page LP may be read first, then the middle page MP may be read, then the upper page UP may be read, and finally the extra page XP may be read.

Referring to FIGS. 7 and 8, when M=4, the maximum number of memory states for multiple QLC memory cells coupled to a word line is 16, that is, sixteen memory states (one erase state (such as Lv0) and fifteen program states (such as Lv1˜Lv15)). In order to obtain data in multiple QLC memory cells coupled to a word line, 15 levels of read voltages are required for comparison, where the lower page LP corresponds to three levels of read voltages, the middle page MP corresponds to four levels of read voltages, the upper page UP corresponds to four levels of read voltages, and the additional page XP corresponds to four levels of read voltages.

In some implementations, the host system sends a third instruction to the memory controller. The third instruction is to instruct to perform a read operation on the write data. The memory controller sends a fourth instruction to the memory device in response to the third instruction. The fourth instruction is to indicate the read level indicator check code (such as LI) and write data (such as LP, MP, UP, and XP data). In response to the fourth instruction, the memory device reads the write data (LP, MP, UP, and XP data) in a first memory cell of the array of memory cells, and reads the level indicator check code LI in a second memory cell, and based on the encoding rule of the level indicator check code LI, perform logical operations with the level indicator check code LI and the read data to reconstruct the write data.

In an implementation of the present disclosure, the read operation is performed by way of a read with level indicator. In some examples, the read with level indicator may be as follows: referring to FIG. 8, when reading LP data, the memory device is configured to apply a set of read voltages (L4+, L6+, L10+) and another set of read voltages (L4−, L6−, L10−) on the word line coupled to a first memory cell, respectively, and obtain two sets of read data (D1 and D2), respectively; apply another set of read voltages on the word line coupled to a second memory cell to acquire the level indicator check code LI; based on the encoding rule of the level indicator check code LI, perform a logical operation with the level indicator check code LI and the two sets of read data (D1 and D2) to reconstruct the write data corresponding to LP, wherein reconstructing the MP, UP, and XP data is also carried out with the above-described method, which will not be repeated here.

In an implementation of the present disclosure, when flip bit count or fail bit count (FBC) in the reconstructed write data exceeds hard decoding capability (such as amount of ECC error correction), a hard decoding operation fails. When the hard decoding operation fails, perform a soft decoding operation. Here and below, taking LP data as an example, the soft decoding operation provided in this disclosure will be described in detail.

In some implementations, the memory controller is further configured to send a first command CMD1 indicating to perform a read operation with a first set of read voltages VreadA, a second set of read voltages VreadB, a third set of read voltages VreadC, and a fourth set of read voltages VreadD. In some examples, the first command CMD1 is to indicate to firstly perform a first read operation with the first set of read voltages VreadA and the second set of read voltages VreadB, and then perform a second read operation with the third set of read voltages VreadC and the fourth set of read voltages VreadD.

The first set of read voltages VreadA and the second set of read voltages VreadB are two sets of preset read voltages with which LP data is read in the way of the read with level indicator. The third set of read voltages VreadC is the offset voltage of the first set of read voltages VreadA. The fourth set of read voltages VreadD is the offset voltage of the second set of read voltages VreadB.

In some examples, each set of the first set of read voltages VreadA, the second set of read voltages VreadB, the third set of read voltages VreadC, and the fourth set of read voltages VreadD corresponds to N levels of read voltages. The i-th level read voltage in the third set of read voltages VreadC is offset with respect to the i-th level read voltage in the first set of read voltages VreadA, and the i-th level read voltage in the fourth set of read voltages VreadD is offset with respect to the i-th level read voltage in the second set of read voltages VreadB. And, the offset direction of the i-th level read voltage in the third set of read voltages VreadC with respect to the i-th level read voltage in the first set of read voltages VreadA is the same as that of the i-th level read voltage in the fourth set of read voltages VreadD with respect to the i-th level read voltage in the second set of read voltages VreadB; N is a positive integer greater than 1, and i is less than or equal to N.

Referring to FIG. 9, FIG. 9 shows a schematic diagram of the distribution relationship between multiple levels of read voltages and threshold voltage, wherein N is equal to 3. That is, the first set of read voltages VreadA corresponds to three levels of read voltages, namely VreadA1, VreadA2, and VreadA3; the second set of read voltages VreadB corresponds to three levels of read voltages, namely VreadB1, VreadB2, and VreadB3; the third set of read voltages VreadC corresponds to three levels of read voltages, namely VreadC1, VreadC2, and VreadC3; and the fourth set of read voltages, VreadD, corresponds to three levels of read voltages, namely VreadD1, VreadD2, and VreadD3.

VreadC1 is offset with respect to VreadA1, VreadC2 is offset with respect to VreadA2, and VreadC3 is offset with respect to VreadA3. VreadD1 is offset with respect to VreadB1, VreadD2 is offset with respect to VreadB2, and VreadD3 is offset with respect to VreadB3. And, the offset direction of VreadC1 with respect to VreadA1 is the same as that of VreadD1 with respect to VreadB1; the offset direction of VreadC2 with respect to VreadA2 is the same as that of VreadD2 with respect to VreadB2; and the offset direction of VreadC3 with respect to VreadA3 is the same as that of VreadD3 with respect to VreadB3.

In some implementations, the N levels of read voltages in the third set of read voltages offset in a negative direction correspondingly with respect to the N levels of read voltages in the first set of read voltages; or, the N levels of read voltages in the third set of read voltages offset in a positive direction correspondingly with respect to the N levels of read voltages in the first set of read voltages; or, a portion of the N levels of read voltages in the third set of read voltages offsets in a negative direction correspondingly with respect to the N levels of read voltages in the first set of read voltages, and another portion of the N levels of read voltages in the third set of read voltages offsets in a positive direction correspondingly with respect to the N levels of read voltages in the first set of read voltages.

In some implementations, VreadC1 offsets in a negative direction with respect to VreadA1, VreadC2 offsets in a negative direction with respect to VreadA2, and VreadC3 offsets in a negative direction with respect to VreadA3.

In some implementations, VreadC1 offsets in a positive direction with respect to VreadA1, VreadC2 offsets in a positive direction with respect to VreadA2, and VreadC3 offsets in a positive direction with respect to VreadA3.

In some implementations, referring to FIG. 9, VreadC1 offsets in a negative direction with respect to VreadA1, VreadC2 offsets in a positive direction with respect to VreadA2, and VreadC3 offsets in a negative direction with respect to VreadA3.

In some implementations, the N levels of read voltages in the fourth set of read voltages offset in a negative direction correspondingly with respect to the N levels of read voltages in the second set of read voltages; or, the N levels of read voltages in the fourth set of read voltages offset in a positive direction correspondingly with respect to the N levels of read voltages in the second set of read voltages; or, a portion of the N levels of read voltages in the fourth set of read voltages offsets in a negative direction correspondingly with respect to the N levels of read voltages in the second set of read voltages, and another portion of the N levels of read voltages in the third set of read voltages offsets in a positive direction correspondingly with respect to the N levels of read voltages in the first set of read voltages.

In some implementations, VreadD1 offsets in a negative direction with respect to VreadB1, VreadD2 offsets in a negative direction with respect to VreadB2, and VreadD3 offsets in a negative direction with respect to VreadB3.

In some implementations, VreadD1 offsets in a positive direction with respect to VreadB1, VreadD2 offsets in a positive direction with respect to VreadB2, and VreadD3 offsets in a positive direction with respect to VreadB3.

In some implementations, referring to FIG. 9, VreadD1 offsets in a negative direction with respect to VreadB1, VreadD2 offsets in a positive direction with respect to VreadB2, and VreadD3 offsets in a negative direction with respect to VreadB3.

In an implementation of the present disclosure, the memory device is configured to: receive the first command CMD1, perform a read operation based on the first set of read voltages VreadA, the second set of read voltages VreadB, the third set of read voltages VreadC, and the fourth set of read voltages VreadD in response to the first command CMD1, to obtain a first set of read data DataA, a second set of read data DataB, a third set of read data DataC, and a fourth set of read data DataD, respectively.

In some examples, perform a read operation with VreadA1, VreadA2, and VreadA3 to obtain the first set of read data DataA; perform a read operation with VreadB1, VreadB2, and VreadB3 to obtain the second set of read data DataB; perform a read operation with VreadC1, VreadC2, and VreadC3 to obtain the third set of read data DataC; and perform a read operation with VreadD1, VreadD2, and VreadD3 to obtain the fourth set of read data DataD.

In an implementation of the present disclosure, the memory controller is further configured to: acquire a first result and a second result, and perform a logic operation on the first result and the second result to obtain first flip information, wherein the first result is obtained based on the first set of read data and the second set of read data, and the second result is obtained based on the third set of read data and the fourth set of read data; and perform a decoding operation based on the first flip information.

Here, the way in which the memory controller acquires the first result and the second result may include multiple methods, and two acquiring ways are described below, such as way 1 and way 2.

Way 1: the memory controller is further configured to send a second command CMD2; and the second command CMD2 is to indicate to acquire the first result and the second result.

The memory device is further configured to receive the second command CMD2; perform a logical operation with the level indicator check code LI and the first set of read data DataA, the second set of read data DataB based on the encoding rule of the level indicator check code LI in response to the second command CMD2, to obtain a first result; and perform a logical operation with the level indicator check code LI and the third set of read data DataC, the fourth set of read data DataD based on the encoding rule of the level indicator check code LI, to obtain a second result; wherein the level indicator check code is obtained by performing an exclusive- or operation on the write data during execution of a write operation.

The memory device is further configured to send the first result and the second result to the memory controller.

Way 2: the memory controller is further configured to send a third command CMD3; and the third command CMD3 is to indicate to acquire the first set of read data DataA, the second set of read data DataB, the third set of read data DataC, and the fourth set of read data DataD, wherein when the level indicator check code LI is cached in the memory controller for backup, the memory controller may directly obtain it; and when the level indicator check code LI is stored in the memory device, the third command CMD3 is also to indicate to acquire the level indicator check code LI.

The memory device is further configured to send the first set of read data DataA, the second set of read data DataB, the third set of read data DataC, and the fourth set of read data DataD to the memory controller in response to the third command CMD3. Here, when the level indicator check code LI is stored in the memory device, the level indicator check code LI is also sent to the memory controller.

The memory controller is further configured to: perform a logical operation with the level indicator check code LI and the first set of read data DataA, the second set of read data DataB based on the encoding rule of the level indicator check code LI, to obtain a first result; and perform a logical operation with the level indicator check code LI, and the third set of read data DataC, the fourth set of read data DataD based on the encoding rule of the level indicator check code LI, to obtain a second result.

In some implementations, the memory controller is further configured to perform a logical operation (such as an XOR operation) on the first result and the second result to obtain first flip information; and perform a decoding operation based on the first flip information. Here, the first flip information is to represent the bits of data that flip in the corresponding data between the first set of read voltages and the third set of read voltages and between the second set of read voltages and the fourth set of read voltages.

In some implementations, the memory controller is further configured to send a fourth command CMD4; and the fourth command CMD4 indicates to perform a read operation with the fifth set of read voltages VreadE and the sixth set of read voltages VreadF. In some examples, the fourth command CMD4 is to indicate to perform a third reading operation with the fifth set of read voltage VreadE and the sixth set of read voltage VreadF by way of a read with level indicator.

The fifth set of read voltages VreadE is the offset voltage of the first set of read voltages VreadA, and the offset direction of the fifth set of read voltages VreadE with respect to the first set of read voltages VreadA is opposite to that of the third set of read voltages VreadC with respect to the first set of read voltages VreadA; and the sixth set of read voltages VreadF is the offset voltage of the second set of read voltages VreadB, and the offset direction of the sixth set of read voltages VreadF with respect to the second set of read voltages VreadB is opposite to that of the fourth set of read voltages VreadD with respect to the second set of read voltages VreadB.

In some examples, each set of the fifth set of read voltages and the sixth set of read voltages corresponds to N levels of read voltages. The offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages; and the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages. And, the offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

Referring to FIG. 9, the fifth set of read voltages VreadE corresponds to three levels of read voltages, namely VreadE1, VreadE2, and VreadE3. The sixth set of read voltages VreadF corresponds to three levels of read voltages, namely VreadF1, VreadF2, and VreadF3. The offset direction of VreadE1 with respect to VreadA1 is the same as that of VreadF1 with respect to VreadB1, and the offset direction of VreadE1 with respect to VreadA1 is opposite to that of VreadC1 with respect to VreadA1. The offset direction of VreadE2 with respect to VreadA2 is the same as that of VreadF2 with respect to VreadB2, and the offset direction of VreadE2 with respect to VreadA2 is opposite to that of VreadC2 with respect to VreadA2. The offset direction of VreadE3 with respect to VreadA3 is the same as that of VreadF3 with respect to VreadB3, and the offset direction of VreadE3 with respect to VreadA3 is opposite to that of VreadC3 with respect to VreadA3.

In some implementations, VreadE1 offsets in a positive direction with respect to VreadA1, VreadE2 offsets in a positive direction with respect to VreadA2, and VreadE3 offsets in a positive direction with respect to VreadA3.

In some implementations, VreadE1 offsets in a negative direction with respect to VreadA1, VreadE2 offsets in a negative direction with respect to VreadA2, and VreadE3 offsets in a negative direction with respect to VreadA3.

In some implementations, referring to FIG. 9, VreadE1 offsets in a positive direction with respect to VreadA1, VreadE2 offsets in a negative direction with respect to VreadA2, and VreadE3 offsets in a positive direction with respect to VreadA3.

In some implementations, VreadF1 offsets in a positive direction with respect to VreadB1, VreadF2 offsets in a positive direction with respect to VreadB2, and VreadF3 offsets in a positive direction with respect to VreadB3.

In some implementations, VreadF1 offsets in a negative direction with respect to VreadB1, VreadF2 offsets in a negative direction with respect to VreadB2, and VreadF3 offsets in a negative direction with respect to VreadB3.

In some implementations, referring to FIG. 9, VreadF1 offsets in a positive direction with respect to VreadB1, VreadF2 offsets in a negative direction with respect to VreadB2, and VreadF3 offsets in a positive direction with respect to VreadB3.

In an implementation of the present disclosure, the memory device is configured to receive the fourth command CMD4; perform a read operation with the fifth set of read voltages VreadE and the sixth set of read voltages VreadF in response to the fourth command CMD4, to obtain a fifth set of read data DataE and a sixth set of read data DataF, respectively. In some examples, perform a read operation with VreadE1, VreadE2, and VreadE3 to obtain the fifth set of read data DataE; perform a read operation with VreadF1, VreadF2, and VreadF3 to obtain the sixth set of read data, DataF.

The memory controller is further configured to: acquire a third result, perform a logical operation on the first result and the third result to obtain second flip information, wherein the third result is obtained based on the fifth set of read data and the sixth set of read data; And perform the decoding operation based on the second flip information.

Similarly, the way by which the memory controller acquires the third result may include multiple ways, and two acquiring ways are described below, such as way 3 and way 4.

Way 3: the memory controller is further configured to send a fifth command CMD5; and the fifth command CMD5 indicates to acquire the third result.

The memory device is further configured to receive the fifth command CMD5; perform an operation on the fifth set of read data DataE and the sixth set of read data DataF in response to the fifth command CMD5, to obtain the third result; and send the third result to the memory controller.

Way 4: the memory controller is further configured to send a sixth command CMD6; and the sixth command CMD6 indicates to acquire the fifth set of read data DataE and the sixth set of read data DataF.

The memory device is configured to send the fifth set of read data DataE and the sixth set of read data DataF to the memory controller in response to the sixth command CMD6.

The memory controller is further configured to perform a logical operation based on the fifth set of read data DataE, the sixth set of read data DataF, and the level indicator check code LI, to obtain the third result.

In some implementations, the memory controller is further configured to perform a logical operation (such as an XOR operation) on the first result and the third result to obtain second flip information. Here, the second flip information is to represent the bits of data that flip in the corresponding data between the first set of read voltages and the fifth set of read voltages and between the second set of read voltages and the sixth set of read voltages.

It should be understood that based on the different places where operations or calculations are performed, the way for command interaction may be other suitable interaction ways in addition to the above-described ways. In addition, it should be noted that the commands or instructions mentioned in the above implementations of the present disclosure may include one or more sequences of commands, and have different forms according to different interface protocol specifications. The present disclosure does not limit this.

Next, perform a decoding operation based on the second flip information.

In some implementations, the memory controller is further configured to acquire confidence levels corresponding to different read voltage intervals. The confidence levels here may be understood as log likelihood ratios (LLRs).

In an implementation of the present disclosure, a first read voltage interval is determined to be between the i-th level read voltage in the first set of read voltages and the i-th level read voltage in the third set of read voltages, the first read voltage interval corresponding to a first confidence level; a second read voltage interval is determined to be between the i-th level read voltage in the second set of read voltages and the i-th level read voltage in the fourth set of read voltages, the second read voltage interval corresponding to a second confidence level; a third read voltage interval is determined to be between the i-th level read voltage in the first set of read voltages and the i-th level read voltage in the fifth set of read voltages, the third read voltage interval corresponding to a third confidence level; and a fourth read voltage interval is determined to be between the i-th level read voltage in the second set of read voltages and the i-th level read voltage in the sixth set of read voltages, the fourth read voltage interval corresponding to a fourth confidence level.

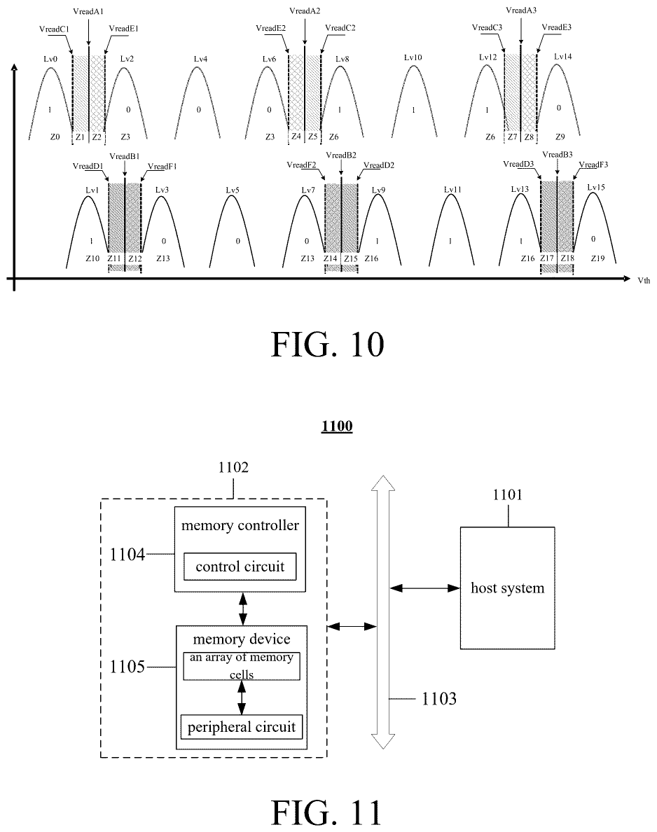

Referring to FIG. 10, FIG. 10 shows a schematic diagram of multiple read voltage intervals, wherein the first read voltage interval includes Z1, Z5, and Z7 intervals; the second read voltage interval includes Z11, Z15, and Z17 intervals; the third read voltage interval includes Z2, Z4, and Z8 intervals; and the fourth read voltage interval includes the Z12, Z14, and Z18 intervals. The first flip information is to represent the bits of data that flip in the data corresponding to the first read voltage interval and the second read voltage interval. The second flip information is to represent the bits of data that flip in the data corresponding to the third read voltage interval and the fourth read voltage interval.

In an implementation of the present disclosure, the first read voltage interval corresponds to the first confidence level LLR1; the second read voltage interval corresponds to the second confidence level LLR2; the third read voltage interval corresponds to the third confidence level LLR3; and the fourth read voltage interval corresponds to the fourth confidence level LLR4. Based on this, the memory controller is further configured to perform a soft decoding operation based on confidence levels corresponding to different read voltage intervals (such as the first confidence level, the second confidence level, the third confidence level, the fourth confidence level) and the first and second flip information to reconstruct LP data. In this way, the soft decoding operation may be performed by obtaining data flipping information for different read voltage intervals and confidence levels corresponding to different read voltage intervals.

It should be noted that a confidence level may be a preset value stored in the memory controller or obtained by calculation of relevant formulas, and the present disclosure does not limit it. In addition, reconstructing MP, UP, and XP data based on methods similar to reconstructing LP data mentioned above has been previously described and will not be repeated here.

It should be noted that, referring to FIGS. 7 and 9, when reading LP data, N is equal to 3. Referring to FIG. 7, when reading MP, UP, or XP data, N is equal to 4. It should be understood that based on the different arrangement of Gray codes for the write data, N may also be equal to other numerical values. In the present disclosure, N equaling to 3 or 4 is taken for illustrative purposes and is not intended to limit the scope of the present disclosure.

In some implementations, the aforementioned soft decoding operation includes Low-Density Parity-Check (LDPC) decoding operation.

In some implementations, the memory system includes a Universal Flash Storage (UFS) or solid-state drive; and the memory device includes a NAND type memory.

Based on the above-described system, an implementation of the present disclosure also proposes a memory controller, configured to: obtain a first result based on the first set of read data and the second set of read data; obtain a second result based on the third set of read data and the fourth set of read data; perform a logical operation on the first result and the second result to obtain first flip information; and perform a decoding operation based on the first flip information; wherein the first set of read data, the second set of read data, the third set of read data, and the fourth set of read data are obtained by performing a read operation via the first set of read voltages, the second set of read voltages, the third set of read voltages, and the fourth set of read voltages, each set of read voltages corresponding to N levels of read voltages. The offset direction of the i-th level read voltage in the third set of read voltages with respect to the i-th level read voltage in the first set of read voltages is the same as that of the i-th level read voltage in the fourth set of read voltages with respect to the i-th level read voltage in the second set of read voltages, N is a positive integer greater than 1, and i is less than or equal to N.

In some implementations, the memory controller is further configured to obtain a third result based on the fifth set of read data and the sixth set of read data; perform a logical operation on the first result and the third result to obtain second flip information; perform a decoding operation based on the second flip information; wherein the fifth set of read data and the sixth set of read data are obtained by performing a read operation via the fifth set of read voltages and the sixth set of read voltages, and the fifth set of read voltages and the sixth set of read voltages correspond to N levels of read voltages, respectively. The offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages. And, the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages. And, the offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

In some implementations, the memory controller is further configured to: acquire a level indicator check code; obtain a first result, a second result, and a third result based on a logical operation of the level indicator check code, wherein the level indicator check code is obtained by an exclusive- or operation on the write data.

In some implementations, the memory controller is further configured to: acquire confidence levels corresponding to different read voltage intervals; and perform a decoding operation based on the confidence levels.

In an implementation of the present disclosure, another system is proposed, which may include an array of memory cells and a control circuit. The array of memory cells and the control circuit may be coupled in any suitable manner, wherein the control circuit may be located in a memory device, such as a peripheral circuit, or located in a memory controller, or located in a host system.

For example, referring to FIG. 11, FIG. 11 shows a block diagram of a system 1100. System 1100 includes a host system 1101 and a memory system 1102. The host system 1101 and the memory system 1102 are connected through an internal bus 1103. Here, the memory system 1102 includes a memory controller 1104 and a memory device 1105 coupled to the memory controller 1104. The memory device 1105 includes an array of memory cells and a peripheral circuit coupled to the array of memory cells. The memory controller 1104 includes a control circuit. In other words, the array of memory cells is located in the memory device, and the control circuit is located in the memory controller.

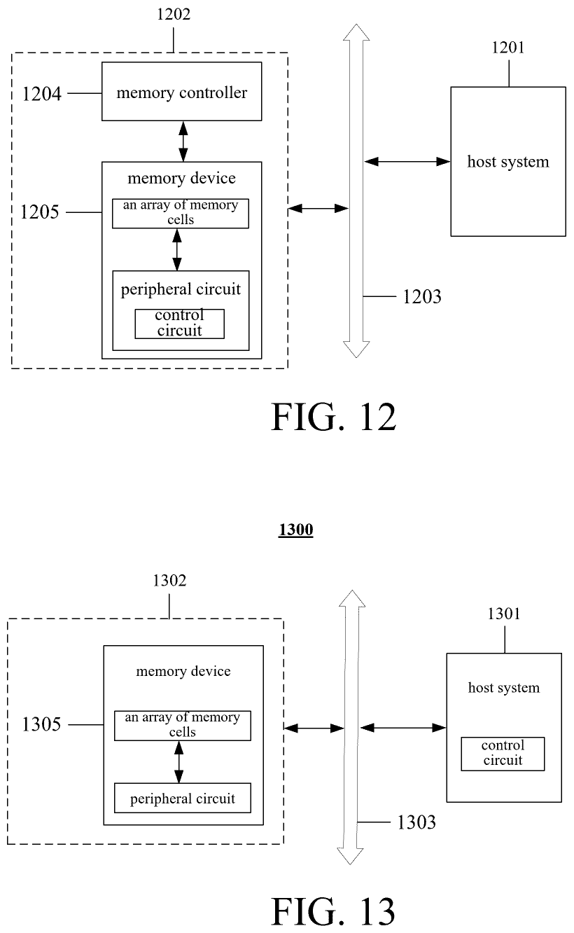

For example, referring to FIG. 12, FIG. 12 shows a block diagram of another system 1200. System 1200 includes a host system 1201 and a memory system 1202. The host system 1201 and the memory system 1202 are connected through an internal bus 1203. Here, the memory system 1202 includes a memory controller 1204 and a memory device 1205 coupled to the memory controller 1204. The memory device 1205 includes an array of memory cells and a peripheral circuit coupled to the array of memory cells, wherein the control circuit is located in the peripheral circuit.

For example, referring to FIG. 13, FIG. 13 shows a block diagram of another system 1300. System 1300 includes a host system 1301 and a memory system 1302. The host system 1301 and the memory system 1302 are connected through an internal bus 1303. Here, the memory system 1302 includes a memory device 1305 which includes an array of memory cells and a peripheral circuit, and a host system 1301 includes a control circuit. In other words, the array of memory cells is located in the memory device, and the control circuit is located in the host system.

In some implementations, the control circuit is configured to perform a read operation on the array of memory cells with a first set of read voltages, a second set of read voltages, a third set of read voltages, and a fourth set of read voltages to acquire a first set of read data, a second set of read data, a third set of read data, and a fourth set of read data, respectively; obtain a first result based on the first set of read data and the second set of read data; obtain a second result based on the third set of read data and the fourth set of read data; perform a logical operation on the first result and the second result to obtain first flip information; perform a decoding operation based on the first flip information, wherein each set of read voltages corresponds to N levels of read voltages. The offset direction of the i-th level read voltage in the third set of read voltages with respect to the i-th level read voltage in the first set of read voltages is the same as that of the i-th level read voltage in the fourth set of read voltages with respect to the i-th level read voltage in the second set of read voltages; N is a positive integer greater than 1, and i is less than or equal to N.

In some implementations, the N levels of read voltages in the third set of read voltages offset in a negative direction correspondingly with respect to the N levels of read voltages in the first set of read voltages; or, the N levels of read voltages in the third set of read voltages offset in a positive direction correspondingly with respect to the N levels of read voltages in the first set of read voltages; or, a portion of the N levels of read voltages in the third set of read voltages offsets in a negative direction correspondingly with respect to the N levels of read voltages in the first set of read voltages, and another portion of the N levels of read voltages in the third set of read voltages offsets in a positive direction correspondingly with respect to the N levels of read voltages in the first set of read voltages.

In some implementations, the control circuit is further configured to: acquire a level indicator check code; the first result and the second result are obtained based on a logical operation of the level indicator check code; wherein the level indicator check code is obtained by performing an exclusive- or operation on the write data.

In some implementations, the control circuit is further configured to perform a read operation on the array of memory cells with the fifth set of read voltages and the sixth set of read voltages to obtain a fifth set of read data and a sixth set of read data, respectively; obtain a third result based on the fifth set of read data and the sixth set of read data; perform a logical operation on the first result and the third result to obtain second flip information; and perform a decoding operation based on the second flip information; wherein the fifth set of read voltages and the sixth set of read voltages correspond to N levels of read voltages, respectively. The offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages. And, the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages. And, the offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

In some implementations, the control circuit is further configured to acquire confidence levels corresponding to different read voltage intervals; and perform a decoding operation based on the confidence levels.

In some implementations, the control circuit is further configured to determine a first read voltage interval being between the i-th level read voltage in the first set of read voltages and the i-th level read voltage in the third set of read voltages, the first read voltage interval corresponding to a first confidence level; determine a second read voltage interval being between the i-th level read voltage in the second set of read voltages and the i-th level read voltage in the fourth set of read voltages, the second read voltage interval corresponding to a second confidence level; determine a third read voltage interval being between the i-th level read voltage in the first set of read voltages and the i-th level read voltage in the fifth set of read voltages, the third read voltage interval corresponding to a third confidence level; determine a fourth read voltage interval being between the i-th level read voltage in the second set of read voltages and the i-th level read voltage in the sixth set of read voltages, the fourth read voltage interval corresponding to a fourth confidence level; and perform a decoding operation with the first confidence level, second confidence level, third confidence level, fourth confidence level, and the first and second flip information.

Thus, in the above-described implementations of the present disclosure, a soft decoding method is provided that supports/adapts the way of read with level indicator, wherein after performing a read operation with two sets of preset read voltages, by adding two sets of offset read voltages and adjusting the offset direction of the offset read voltages to obtain data flip information of different read voltage intervals and performing the soft decoding operation based on the data flip information, it is enabled to provide more targeted decoding and error correction for flipped bits of data, thereby improving decoding success rate and further improving error correction performance and reading performance of the memory system. On the other hand, the soft decoding operation may identify the flipped bits of data in the separated memory states appearing in the overlapping regions, prolonging the readable-back life of coarse data and further improving error correction performance and the reading performance of the memory system.

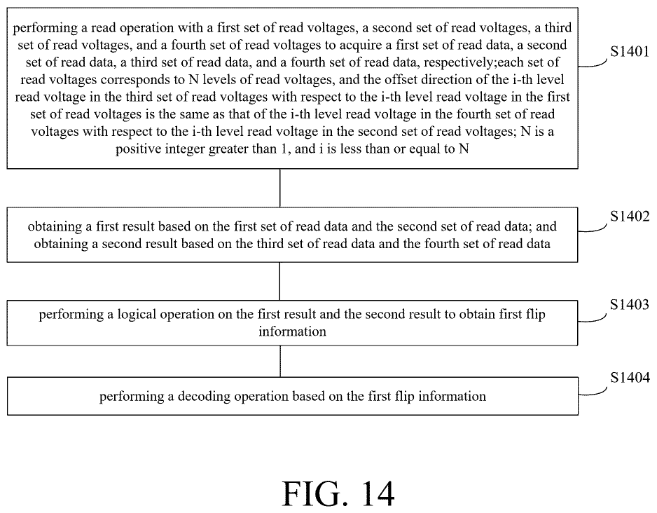

Based on the above-described memory system, an implementation of the present disclosure also provides a method of operating a system, referring to FIG. 14, the operating method comprising:

Operation S1401: performing a read operation with a first set of read voltages, a second set of read voltages, a third set of read voltages, and a fourth set of read voltages to obtain a first set of read data, a second set of read data, a third set of read data, and a fourth set of read data, respectively.

Operation S1402: obtaining a first result based on the first set of read data and the second set of read data; and obtaining a second result based on the third set of read data and the fourth set of read data.

Operation S1403: performing a logical operation on the first result and the second result to obtain first flip information.

Operation S1404: performing a decoding operation based on the first flip information.

Each set of read voltages corresponds to N levels of read voltages. The offset direction of the i-th level read voltage in the third set of read voltages with respect to the i-th level read voltage in the first set of read voltages is the same as that of the i-th level read voltage in the fourth set of read voltages with respect to the i-th level read voltage in the second set of read voltages; N is a positive integer greater than 1, and i is less than or equal to N.

In some implementations, the N levels of read voltages in the third set of read voltages offset in a negative direction correspondingly with respect to the N levels of read voltages in the first set of read voltages; or, the N levels of read voltages in the third set of read voltages offset in a positive direction correspondingly with respect to the N levels of read voltages in the first set of read voltages; or, a portion of the N levels of read voltages in the third set of read voltages offsets in a negative direction correspondingly with respect to the N levels of read voltages in the first set of read voltages, and another portion of the N levels of read voltages in the third set of read voltages offsets in a positive direction correspondingly with respect to the N levels of read voltages in the first set of read voltages.

In some implementations, the method further comprises: obtaining a level indicator check code, wherein the level indicator check code is obtained by an exclusive-or operation on the write data, wherein the first result and the second result are obtained based on a logical operation of the level indicator check code.

In some implementations, the method further comprises: performing a read operation with a fifth set of read voltages and a sixth set of read voltages to obtain a fifth set of read data and a sixth set of read data, respectively; obtaining a third result based on the fifth set of read data and the sixth set of read data; performing a logical operation on the first result and the third result to obtain second flip information; and performing a decoding operation based on the second flip information.

The fifth set of read voltages and the sixth set of read voltages correspond to N levels of read voltages, respectively. The offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages. And, the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages. And, the offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

In some implementations, the method further comprises: obtaining confidence levels corresponding to different read voltage intervals; and performing a decoding operation based on the confidence levels.

In some implementations, performing a decoding operation based on the confidence levels includes: determining a first read voltage interval being between the i-th level read voltage in the first set of read voltages and the i-th level read voltage in the third set of read voltages, the first read voltage interval corresponding to a first confidence level; determining a second read voltage interval being between the i-th level read voltage in the second set of read voltages and the i-th level read voltage in the fourth set of read voltages, the second read voltage interval corresponding to a second confidence level; determining a third read voltage interval being between the i-th level read voltage in the first set of read voltages and the i-th level read voltage in the fifth set of read voltages, the third read voltage interval corresponding to a third confidence level; determining a fourth read voltage interval being between the i-th level read voltage in the second read voltage group and the i-th level read voltage in the sixth read voltage group, the fourth read voltage interval corresponding to a fourth confidence level; and performing a decoding operation with the first confidence level, second confidence level, third confidence level, fourth confidence level, and the first and second flip information.

Based on the above-described memory system and its operating method, an implementation of the present disclosure also provides a non-transient computer-readable storage medium storing executable instructions thereon, when executed by the memory system, the executable instructions may implement the steps of the operating method of the system in the above implementations of the present disclosure.

In some implementations, the non-transient computer-readable storage medium may be ferromagnetic random access memory (FRAM), read only memory (ROM), programmable read only memory (PROM), erasable programmable read only memory (EPROM), electrically erasable programmable read only memory (EEPROM), flash memory, magnetic surface memory, optical disc, or compact disc read only memory (CD-ROM), etc. or various devices including one or any combination of the above-mentioned memory devices.

In some implementations, executable instructions may take the form of programs, software, software modules, scripts, or code, written in any form of programming language (including compiled or interpreted languages, or declarative or procedural languages), and may be deployed in any form, including as standalone programs or as modules, components, subroutines, or other units suitable for use in a computing environment.

As an example, executable instructions may not necessarily correspond to files in a file system, and may be stored in a portion of a file that stores other programs or data, such as in one or more scripts in a Hyper Text Markup Language (HTML) document, in a single file dedicated to the program discussed, or in multiple collaborative files (e.g., files that store one or more modules, subroutines, or code parts).

As an example, executable instructions may be deployed to execute on a memory system, or on multiple electronic devices located in one location, or on multiple electronic devices distributed across multiple locations and interconnected through a communication network.

It should be understood that the term “one implementation” or “an implementation” mentioned throughout the specification means that specific features, structures, or characteristics related to the implementations are included in at least one implementation of the present disclosure. Therefore, the phrase “in one implementation” or “in an implementation” that appears throughout the specification may not necessarily refer to the same implementation. In addition, these specific features, structures, or characteristics may be combined in one or more implementations in any suitable manner. It should be understood that in the various implementations of the present disclosure, the size of the serial numbers of the above processes does not imply the order of execution. The order of execution of each process should be determined by its function and internal logic, and should not constitute any limitation on the implementation process of implementations of the present disclosure. The serial numbers of the above implementations of the present disclosure are just for description and do not represent the advantages or disadvantages of the implementations.

The methods disclosed in the several method implementations provided in the present disclosure may be combined arbitrarily without conflict to obtain a new method implementation.

Based on this, an implementation of the present disclosure proposes a memory controller, a memory system, a system and operation method, and a storage medium. On one hand, an implementation of the present disclosure provides a memory controller configured to: obtain a first result based on a first set of read data and a second set of read data; obtain a second result based on a third set of read data and a fourth set of read data; perform a logic operation on the first result and the second result to obtain first flip information; perform a decoding operation based on the first flip information; wherein the first set of read data, the second set of read data, the third set of read data, and the fourth set of read data are obtained by performing a read operation via a first set of read voltages, a second set of read voltages, a third set of read voltages, and a fourth set of read voltages, each set of read voltages corresponding to N levels of read voltages; and the offset direction of the i-th level read voltage in the third set of read voltages with respect to the i-th level read voltage in the first set of read voltages is the same as that of the i-th level read voltage in the fourth set of read voltages with respect to the i-th level read voltage in the second set of read voltages, wherein N is a positive integer greater than 1, and i is less than or equal to N.

In some implementations, the memory controller is further configured to: obtain a third result based on a fifth set of read data and a sixth set of read data; perform a logic operation on the first result and the third result to obtain second flip information; perform the decoding operation based on the second flip information; wherein the fifth set of read data and the sixth set of read data are obtained by performing a read operation via a fifth set of read voltages and a sixth set of read voltages, the fifth set of read voltages and the sixth set of read voltages corresponding to N levels of read voltages, respectively, and the offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages, and the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages; and the offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

In some implementations, the memory controller is further configured to: acquire a level indicator check code; and obtain the first result, the second result, and the third result based on a logic operation of the level indicator check code, wherein the level indicator check code is obtained by performing an exclusive- or operation on write data.

In some implementations, the memory controller is further configured to: acquire confidence levels corresponding to different read voltage intervals; and perform the decoding operation based on the confidence levels.

An implementation of the present disclosure further provides a memory system comprising a memory device and a memory controller coupled to the memory device and configured to send a first command indicating to perform a read operation with a first set of read voltages, a second set of read voltages, a third set of read voltages, and a fourth set of read voltages; wherein the memory device is configured to: perform the read operation based on the first set of read voltages, the second set of read voltages, the third set of read voltages, and the fourth set of read voltages in response to the first command, to obtain a first set of read data, a second set of read data, a third set of read data, and a fourth set of read data, respectively; and the memory controller is further configured to: acquire a first result and a second result, and perform a logic operation on the first result and the second result to obtain first flip information, wherein the first result is obtained based on the first set of read data and the second set of read data, and the second result is obtained based on the third set of read data and the fourth set of read data; and perform a decoding operation based on the first flip information; wherein each set of read voltages corresponds to N levels of read voltages, and the offset direction of the i-th level read voltage in the third set of read voltages with respect to the i-th level read voltage in the first set of read voltages is the same as that of the i-th level read voltage in the fourth set of read voltages with respect to the i-th level read voltage in the second set of read voltages; N is a positive integer greater than 1, and i is less than or equal to N.

In some implementations, the memory controller is further configured to: send a second command indicating to acquire the first result and the second result; and the memory device is configured to: obtain a first result according to a logic operation of the first set of read data, the second set of read data, and a level indicator check code in response to the second command; obtain a second result according to a logic operation of the third set of read data, the fourth set of read data and the level indicator check code; and send the first result and the second result to the memory controller; wherein the level indicator check code is obtained by performing an exclusive- or operation on write data.

In some implementations, the memory controller is further configured to send a third command indicating to acquire the first set of read data, the second set of read data, the third set of read data, and the fourth set of read data; the memory device is configured to send the first set of read data, the second set of read data, the third set of read data, and the fourth set of read data to the memory controller in response to the third command; and the memory controller is further configured to obtain a first result according to a logic operation of the first set of read data, the second set of read data, and a level indicator check code, and obtain a second result according to a logic operation of the third set of read data, the fourth set of read data, and the level indicator check code; wherein the level indicator check code is obtained by performing an exclusive- or operation on write data.

In some implementations, the memory controller is further configured to send a fourth command indicating to perform a read operation with a fifth set of read voltages and a sixth set of read voltages; the memory device is configured to perform the read operation with the fifth set of read voltages and the sixth set of read voltages in response to the fourth command, to obtain a fifth set of read data and a sixth set of read data, respectively; and the memory controller is further configured to acquire a third result, perform a logic operation on the first result and the third result to obtain second flip information, wherein the third result is obtained based on the fifth set of read data and the sixth set of read data, and perform the decoding operation based on the second flip information; wherein the fifth set of read voltages and the sixth set of read voltages correspond to N levels of read voltages, respectively, the offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages, and the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages; and the offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

In some implementations, the memory controller is further configured to send a fifth command indicating to acquire the third result; and the memory device is configured to obtain a third result according to a logic operation of the fifth set of read data, the sixth set of read data and the level indicator check code in response to the fifth command, and send the third result to the memory control.

In some implementations, the memory controller is further configured to send a sixth command indicating to acquire a fifth set of read data and a sixth set of read data; the memory device is configured to send the fifth set of read data and the sixth set of read data to the memory controller in response to the sixth command; and the memory control is further configured to obtain the third result according to a logic operation of the fifth set of read data, the sixth set of read data and the level indicator check code.

An implementation of the present disclosure further provides a system, comprising an array of memory cells and a control circuit coupled to the array of memory cells and configured to: perform a read operation on the array of memory cells with a first set of read voltages, a second set of read voltages, a third set of read voltages, and a fourth set of read voltages to acquire a first set of read data, a second set of read data, a third set of read data, and a fourth set of read data, respectively; obtain a first result based on the first set of read data and the second set of read data; obtain a second result based on the third set of read data and the fourth set of read data; perform a logic operation on the first result and the second result to obtain first flip information; and perform a decoding operation based on the first flip information; wherein each set of read voltages corresponds to N levels of read voltages, and the offset direction of the i-th level read voltage in the third set of read voltages with respect to the i-th level read voltage in the first set of read voltages is the same as that of the i-th level read voltage in the fourth set of read voltages with respect to the i-th level read voltage in the second set of read voltages; N is a positive integer greater than 1, and i is less than or equal to N.

In some implementations, the N levels of read voltages in the third set of read voltages offset in a negative direction correspondingly with respect to the N levels of read voltages in the first set of read voltages, or the N levels of read voltages in the third set of read voltages offset in a positive direction correspondingly with respect to the N levels of read voltages in the first set of read voltages; or a portion of the N levels of read voltages in the third set of read voltages offsets in a negative direction correspondingly with respect to the N levels of read voltages in the first set of read voltages, and another portion of the N levels of read voltages in the third set of read voltages offsets in a positive direction correspondingly with respect to the N levels of read voltages in the first set of read voltages.

In some implementations, the control circuit is further configured to: acquire a level indicator check code; and the first result and the second result are obtained based on a logic operation of the level indicator check code, wherein the level indicator check code is obtained by performing an exclusive- or operation on write data.

In some implementations, the control circuit is further configured to: perform a read operation on the array of memory cells with a fifth set of read voltages and a sixth set of read voltages to acquire a fifth set of read data and a sixth set of read data, respectively; obtain a third result based on the fifth set of read data and the sixth set of read data; perform a logic operation on the first result and the third result to obtain second flipping information; and perform the decoding operation based on the second flip information; wherein the fifth set of read voltages and the sixth set of read voltages correspond to N levels of read voltages, respectively, the offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages, and the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages; and the offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

In some implementations, the control circuit is further configured to: acquire confidence levels corresponding to different read voltage intervals; and perform the decoding operation based on the confidence levels.

In some implementations, the control circuit is further configured to:

determine a first read voltage interval being between the i-th level read voltage in the first set of read voltages and the i-th level read voltage in the third set of read voltages, the first read voltage interval corresponding to a first confidence level; determine a second read voltage interval being between the i-th level read voltage in the second set of read voltages and the i-th level read voltage in the fourth set of read voltages, the second read voltage interval corresponding to a second confidence level; determine a third read voltage interval being between the i-th level read voltage in the first set of read voltages and the i-th level read voltage in the fifth set of read voltages, the third read voltage interval corresponding to a third confidence level; determine a fourth read voltage interval being between the i-th level read voltage in the second set of read voltages and the i-th level read voltage in the sixth set of read voltages, the fourth read voltage interval corresponding to a fourth confidence level; and perform the decoding operation with the first confidence level, the second confidence level, the third confidence level, the fourth confidence level, and the first flip information and the second flip information.

In some implementations, the system comprises: a memory device, and a memory controller coupled to the memory device; the array of memory cells is located in the memory device, and the control circuit is located in the memory controller.

In some implementations, the system comprises: a memory device, wherein the memory device comprises the array of memory cells and a peripheral circuit coupled to the array of memory cells, and the control circuit is located in the peripheral circuit.

In some implementations, the system comprises: a memory device, and a host system coupled to the memory device, wherein the array of memory cells is located in the memory device, and the control circuit is located in the host system.

In some implementations, the array of memory cells comprises a plurality of memory cells, wherein the N is equal to 3 or 4 when the memory cells are configured to store four bits of data.

In some implementations, the decoding operation comprises a low-density parity-check decoding operation.

An implementation of the present disclosure further provides a method of operating a system, the operating method comprising: performing a read operation with a first set of read voltages, a second set of read voltages, a third set of read voltages, and a fourth set of read voltages to acquire a first set of read data, a second set of read data, a third set of read data, and a fourth set of read data, respectively; obtaining a first result based on the first set of read data and the second set of read data; obtaining a second result based on the third set of read data and the fourth set of read data; performing a logic operation on the first result and the second result to obtain first flip information; and performing a decoding operation based on the first flip information; wherein each set of read voltages corresponds to N levels of read voltages, and the offset direction of the i-th level read voltage in the third set of read voltages with respect to the i-th level read voltage in the first set of read voltages is the same as that of the i-th level read voltage in the fourth set of read voltages with respect to the i-th level read voltage in the second set of read voltages; N is a positive integer greater than 1, and i is less than or equal to N.

In some implementations, the N levels of read voltages of the third set of read voltages offset in a negative direction correspondingly with respect to the N levels of read voltages of the first set of read voltages; or the N levels of read voltages of the third set of read voltages offset in a positive direction correspondingly with respect to the N levels of read voltages of the first set of read voltages; Or a portion of the N levels of read voltages in the third set of read voltages offsets in a negative direction correspondingly with respect to the N levels of read voltages in the first set of read voltages, and another portion of the N levels of read voltages in the third set of read voltages offsets in a positive direction correspondingly with respect to the N levels of read voltages in the first set of read voltages.

In some implementations, the method further comprises acquiring a level indicator check code, wherein the level indicator check code is obtained by performing an exclusive- or operation on write data; wherein the first result and the second result are obtained based on a logical operation of the level indicator check code.

In some implementations, the method further comprises: performing a read operation with a fifth set of read voltages and a sixth set of read voltages to acquire a fifth set of read data and a sixth set of read data, respectively; obtaining a third result based on the fifth set of read data and the sixth set of read data; performing a logic operation on the first result and the third result to obtain second flip information; and performing the decoding operation based on the second flip information; wherein the fifth set of read voltages and the sixth set of read voltages correspond to N levels of read voltages, respectively; the offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages, and the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages; and the offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

In some implementations, the method further comprises: acquiring confidence levels corresponding to different read voltage intervals; and performing the decoding operation based on the confidence levels.

In some implementations, the performing the decoding operation based on the confidence levels comprises: determining a first read voltage interval being between the i-th level read voltage in the first set of read voltages and the i-th level read voltage in the third set of read voltages, the first read voltage interval corresponding to a first confidence level; determining a second read voltage interval being between the i-th level read voltage in the second set of read voltages and the i-th level read voltage in the fourth set of read voltages, the second read voltage interval corresponding to a second confidence level; determining a third read voltage interval being between the i-th level read voltage in the first set of read voltages and the i-th level read voltage in the fifth set of read voltages, the third read voltage interval corresponding to a third confidence level; determining a fourth read voltage interval being between the i-th level read voltage in the second set of read voltages and the i-th level read voltage in the sixth set of read voltages, the fourth read voltage interval corresponding to a fourth confidence level; and performing the decoding operation with the first confidence level, the second confidence level, the third confidence level, the fourth confidence level, and the first flip information and the second flip information.

An implementation of the present disclosure further provides a non-transitory computer-readable storage medium having stored thereon a computer program which, when executed by a processor, performs the operating method as the above-described implementations of the present disclosure.

In the implementations of the present disclosure, a soft decoding method is provided that supports/adapts the way of a read with level indicator, wherein after performing a read operation with two sets of preset read voltages, by adding two sets of offset read voltages and adjusting the offset direction of the offset read voltages to obtain data flip information of different read voltage intervals and performing the soft decoding operation based on the data flip information, it is enabled to provide more targeted decoding and error correction for flipped bits of data, thereby improving decoding success rate, prolonging data's read back life, and improving error correction performance and reading performance of the memory system.

The above are only implementations of the present disclosure, but the scope of protection of the present disclosure is not limited to this. Any skilled in the art may easily conceive of changes or substitutions within the technical scope disclosed in the present disclosure, which should be included in the scope of the present disclosure. Therefore, the scope of the present disclosure should be based on the scope of the claims.

What is claimed is:

1. A memory system, comprising:
a memory device; and
a memory controller coupled to the memory device and configured to:
send a first command indicating to perform a read operation with a first set of read voltages, a second set of read voltages, a third set of read voltages, and a fourth set of read voltages;
wherein the memory device is configured to:
perform the read operation based on the first set of read voltages, the second set of read voltages, the third set of read voltages, and the fourth set of read voltages in response to the first command, and
obtain a first set of read data, a second set of read data, a third set of read data, and a fourth set of read data, respectively; and
the memory controller is further configured to:
acquire a first result and a second result, and perform a logic operation on the first result and the second result to obtain first flip information, wherein the first result is obtained based on the first set of read data and the second set of read data, and the second result is obtained based on the third set of read data and the fourth set of read data; and
perform a decoding operation based on the first flip information;
wherein each set of read voltages corresponds to N levels of read voltages, and an offset direction of an i-th level read voltage in the third set of read voltages with respect to the i-th level read voltage in the first set of read voltages is the same as that of the i-th level read voltage in the fourth set of read voltages with respect to the i-th level read voltage in the second set of read voltages, wherein N is a positive integer greater than 1, and i is less than or equal to N.

2. The memory system of claim 1, wherein:
the memory controller is further configured to send a second command indicating to acquire the first result and the second result; and
the memory device is configured to:
obtain the first result according to a logic operation of the first set of read data, the second set of read data, and a level indicator check code in response to the second command;
obtain the second result according to a logic operation of the third set of read data, the fourth set of read data, and the level indicator check code; and
send the first result and the second result to the memory controller;
wherein the level indicator check code is obtained by performing an exclusive-or operation on write data.

3. The memory system of claim 1, wherein:
the memory controller is further configured to send a third command indicating to acquire the first set of read data, the second set of read data, the third set of read data, and the fourth set of read data;
the memory device is configured to send the first set of read data, the second set of read data, the third set of read data, and the fourth set of read data to the memory controller in response to the third command; and
the memory controller is further configured to:
obtain the first result according to a logic operation of the first set of read data, the second set of read data, and a level indicator check code, and
obtain the second result according to a logic operation of the third set of read data, the fourth set of read data, and the level indicator check code;
wherein the level indicator check code is obtained by performing an exclusive-or operation on write data.

4. The memory system of claim 2, wherein:
the memory controller is further configured to send a fourth command indicating to perform a read operation with a fifth set of read voltages and a sixth set of read voltages;
the memory device is configured to:
perform the read operation with the fifth set of read voltages and the sixth set of read voltages in response to the fourth command, and
obtain a fifth set of read data and a sixth set of read data, respectively; and
the memory controller is further configured to:
acquire a third result,
perform a logic operation on the first result and the third result to obtain second flip information, wherein the third result is obtained based on the fifth set of read data and the sixth set of read data, and
perform the decoding operation based on the second flip information;
wherein:
the fifth set of read voltages and the sixth set of read voltages correspond to N levels of read voltages, respectively, an offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages; and
the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages, and an offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

5. The memory system of claim 4, wherein:
the memory controller is further configured to send a fifth command indicating to acquire the third result; and
the memory device is configured to:
obtain the third result according to a logic operation of the fifth set of read data, the sixth set of read data and the level indicator check code in response to the fifth command; and
send the third result to the memory controller.

6. The memory system of claim 4, wherein:
the memory controller is further configured to send a sixth command indicating to acquire a fifth set of read data and a sixth set of read data;
the memory device is configured to send the fifth set of read data and the sixth set of read data to the memory controller in response to the sixth command; and
the memory controller is further configured to obtain the third result according to a logic operation of the fifth set of read data, the sixth set of read data, and the level indicator check code.

7. A system, comprising:
an array of memory cells; and
a control circuit coupled to the array of memory cells and configured to:
perform a read operation on the array of memory cells with a first set of read voltages, a second set of read voltages, a third set of read voltages, and a fourth set of read voltages to acquire a first set of read data, a second set of read data, a third set of read data, and a fourth set of read data, respectively;
obtain a first result based on the first set of read data and the second set of read data;
obtain a second result based on the third set of read data and the fourth set of read data;
perform a logic operation on the first result and the second result to obtain first flip information; and
perform a decoding operation based on the first flip information;
wherein each set of read voltages corresponds to N levels of read voltages, and an offset direction of an i-th level read voltage in the third set of read voltages with respect to the i-th level read voltage in the first set of read voltages is the same as that of the i-th level read voltage in the fourth set of read voltages with respect to the i-th level read voltage in the second set of read voltages, wherein N is a positive integer greater than 1, and i is less than or equal to N.

8. The system of claim 7, wherein the N levels of read voltages in the third set of read voltages offset in a negative direction correspondingly with respect to the N levels of read voltages in the first set of read voltages, or the N levels of read voltages in the third set of read voltages offset in a positive direction correspondingly with respect to the N levels of read voltages in the first set of read voltages; or a portion of the N levels of read voltages in the third set of read voltages offsets in the negative direction correspondingly with respect to the N levels of read voltages in the first set of read voltages, and another portion of the N levels of read voltages in the third set of read voltages offset in the positive direction correspondingly with respect to the N levels of read voltages in the first set of read voltages.

9. The system of claim 7, wherein the control circuit is further configured to:
acquire a level indicator check code; and
wherein the first result and the second result are obtained based on a logic operation of the level indicator check code, the level indicator check code is obtained by performing an exclusive- or operation on write data.

10. The system of claim 9, wherein the control circuit is further configured to:
perform a read operation on the array of memory cells with a fifth set of read voltages and a sixth set of read voltages to acquire a fifth set of read data and a sixth set of read data, respectively;
obtain a third result based on the fifth set of read data and the sixth set of read data;
perform a logic operation on the first result and the third result to obtain second flip information; and
perform the decoding operation based on the second flip information, wherein:
the fifth set of read voltages and the sixth set of read voltages correspond to N levels of read voltages, respectively, an offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages, and
the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages, and an offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

11. The system of claim 10, wherein the control circuit is further configured to:
acquire confidence levels corresponding to different read voltage intervals; and
perform the decoding operation based on the confidence levels.

12. The system of claim 11, wherein the control circuit is further configured to:
determine a first read voltage interval being between the i-th level read voltage in the first set of read voltages and the i-th level read voltage in the third set of read voltages, the first read voltage interval corresponding to a first confidence level;
determine a second read voltage interval being between the i-th level read voltage in the second set of read voltages and the i-th level read voltage in the fourth set of read voltages, the second read voltage interval corresponding to a second confidence level;
determine a third read voltage interval being between the i-th level read voltage in the first set of read voltages and the i-th level read voltage in the fifth set of read voltages, the third read voltage interval corresponding to a third confidence level;
determine a fourth read voltage interval being between the i-th level read voltage in the second set of read voltages and the i-th level read voltage in the sixth set of read voltages, the fourth read voltage interval corresponding to a fourth confidence level; and
perform the decoding operation with the first confidence level, the second confidence level, the third confidence level, the fourth confidence level, and the first flip information and the second flip information.

13. The system of claim 7, comprising:
a memory device; and
a memory controller coupled to the memory device;
wherein the array of memory cells is located in the memory device, and the control circuit is located in the memory controller.

14. The system of claim 7, comprising: a memory device, wherein the memory device comprises the array of memory cells and a peripheral circuit coupled to the array of memory cells, and the control circuit is located in the peripheral circuit.

15. A method of operating a system, comprising:
performing a read operation with a first set of read voltages, a second set of read voltages, a third set of read voltages, and a fourth set of read voltages to acquire a first set of read data, a second set of read data, a third set of read data, and a fourth set of read data, respectively;
obtaining a first result based on the first set of read data and the second set of read data;
obtaining a second result based on the third set of read data and the fourth set of read data;
performing a logic operation on the first result and the second result to obtain first flip information; and
performing a decoding operation based on the first flip information;
wherein each set of read voltages corresponds to N levels of read voltages, and an offset direction of an i-th level read voltage in the third set of read voltages with respect to the i-th level read voltage in the first set of read voltages is the same as that of the i-th level read voltage in the fourth set of read voltages with respect to the i-th level read voltage in the second set of read voltages, wherein N is a positive integer greater than 1, and i is less than or equal to N.

16. The method of claim 15, wherein the N levels of read voltages of the third set of read voltages offset in a negative direction correspondingly with respect to the N levels of read voltages of the first set of read voltages, or the N levels of read voltages of the third set of read voltages offset in a positive direction correspondingly with respect to the N levels of read voltages of the first set of read voltages, or a portion of the N levels of read voltages in the third set of read voltages offsets in a negative direction correspondingly with respect to the N levels of read voltages in the first set of read voltages, and another portion of the N levels of read voltages in the third set of read voltages offsets in a positive direction correspondingly with respect to the N levels of read voltages in the first set of read voltages.

17. The method of claim 15, further comprising:
acquiring a level indicator check code, wherein the level indicator check code is obtained by performing an exclusive- or operation on write data;
wherein the first result and the second result are obtained based on a logical operation of the level indicator check code.

18. The method of claim 17, further comprising:
performing a read operation with a fifth set of read voltages and a sixth set of read voltages to acquire a fifth set of read data and a sixth set of read data, respectively;
obtaining a third result based on the fifth set of read data and the sixth set of read data;
performing a logic operation on the first result and the third result to obtain second flip information; and
performing the decoding operation based on the second flip information, wherein:
the fifth set of read voltages and the sixth set of read voltages correspond to N levels of read voltages, respectively, an offset direction of the i-th level read voltage in the fifth set of read voltages with respect to the i-th level read voltage in the first set of read voltages is the same as that of the i-th level read voltage in the sixth set of read voltages with respect to the i-th level read voltage in the second set of read voltages, and
the offset direction of the i-th level read voltage in the fifth set of read voltages with respect to the i-th level read voltage in the first set of read voltages is opposite to that of the i-th level read voltage in the third set of read voltages with respect to the i-th level read voltage in the first set of read voltages; and an offset direction of the i-th level read voltage in the sixth set of read voltages with respect to the i-th level read voltage in the second set of read voltages is opposite to that of the i-th level read voltage in the fourth set of read voltages with respect to the i-th level read voltage in the second set of read voltages.

19. The method of claim 18, further comprising:
acquiring confidence levels corresponding to different read voltage intervals; and
performing the decoding operation based on the confidence levels.

20. The method of claim 19, wherein the performing of the decoding operation based on the confidence levels comprises:
determining a first read voltage interval being between the i-th level read voltage in the first set of read voltages and the i-th level read voltage in the third set of read voltages, the first read voltage interval corresponding to a first confidence level;
determining a second read voltage interval being between the i-th level read voltage in the second set of read voltages and the i-th level read voltage in the fourth set of read voltages, the second read voltage interval corresponding to a second confidence level;
determining a third read voltage interval being between the i-th level read voltage in the first set of read voltages and the i-th level read voltage in the fifth set of read voltages, the third read voltage interval corresponding to a third confidence level;
determining a fourth read voltage interval being between the i-th level read voltage in the second set of read voltages and the i-th level read voltage in the sixth set of read voltages, the fourth read voltage interval corresponding to a fourth confidence level; and
performing the decoding operation with the first confidence level, the second confidence level, the third confidence level, the fourth confidence level, and the first flip information and the second flip information.
